(19) United States
(12) Patent Application Publication
(10) Pub. No.: US 2007/0025085 A1
(43) Pub. Date: Feb. 1, 2007

(54) Heat sink

(75) Inventor: Chun-Yi Chang, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Chen City (TW)

(21) Appl. No.: 11/416,550

(22) Filed: May 3, 2006

(30) Foreign Application Priority Data
Jul. 29, 2005 (TW) 094125760

(51) Int. Cl. H05K 7/20

(52) U.S. Cl. 361/704

(57) ABSTRACT

A heat sink is disclosed in accordance with a preferred embodiment. The heat sink mainly includes a base, a plurality of fins, and a working fluid. The base defines a receiving space therein. The fins extend from the base. Each fin defines a cavity in communication with the receiving space of the base. The working fluid is hermetically contained inside the receiving space.

### TECHNICAL FIELD

The present invention relates to heat dissipation devices and, more particularly, to a fins-type heat sink.

### BACKGROUND

At present, electronic components such as semiconductor chips are becoming progressively smaller, while at the same time heat dissipation requirements thereof are increasing. Generally, heat dissipation devices are applied to the electronic components in order to facilitate radiation of heat from the electronic components.

Numerous kinds of heat dissipation devices have been developed for cooling down the electronic components, for example, heat sinks. A conventional heat sink includes a base and a number of fins extending from a surface of the base. In general, the base and the fins are separately formed, and are then joined together. There are two typical ways to join the fins and the base together. One way is to employ a thermal adhesive, an epoxy resin or the like between the fins and the base, whereby the base and the fins are in effect indirectly joined together. The other way is to employ forging pressing, melting, soldering or the like to in effect directly join the fins and the base together.

A typical soldered fin heat sink assembly can be formed by the steps of: placing a sheet or paste of Sn—Zn (tin-zinc) solder upon a copper base; placing a folded aluminum fin assembly on the solder sheet or paste; heating the base, the folded fin assembly and the solder to a temperature exceeding the liquidus temperature of the solder, and allowing the solder to flow; and cooling the solder to form a soldered joint between the base and the folded fin assembly.

However, the soldering process is relatively complicated and time-consuming. In addition, the interposed solder causes thermal resistance between the base and the fins. As a result, the heat transfer efficiency of the heat sink assembly is relatively lower.

Additionally, typically, the heat sink employs solid base and fins. This solid base and fins unduly have a heavy weight and thus are unsuitable for a lightweight requirement of current electronic products.

What is needed, therefore, is a heat sink which is lightweight and has relatively lower thermal resistance.

### SUMMARY

In accordance with a preferred embodiment, a heat sink includes a base, a plurality of fins, and a working fluid. The base defines a receiving space therein. The fins extend from the base. Each fin defines a cavity in communication with the receiving space of the base. The working fluid is hermetically contained inside the receiving space.

Other advantages and novel features will become more apparent from the following detailed description of embodiments when taken in conjunction with the accompanying drawings.

### BRIEF DESCRIPTION OF THE DRAWINGS

Many aspects of the present heat sink can be better understood with reference to the following drawings. The components in the drawings are not necessarily to scale, the emphasis instead being placed upon clearly illustrating the principles of the present heat sink. Moreover, in the drawings, like reference numerals designate corresponding parts throughout the several views.

FIG. 1 is a schematic, cross-section view of a heat sink in according with a preferred embodiment; and

FIG. 2 is similar to FIG. 1, but showing an application of the heat sink of FIG. 1 to a heat-generating element.

### DETAILED DESCRIPTION OF THE EMBODIMENTS

Embodiments of the present heat sink will now be described in detail below with reference to the drawings.

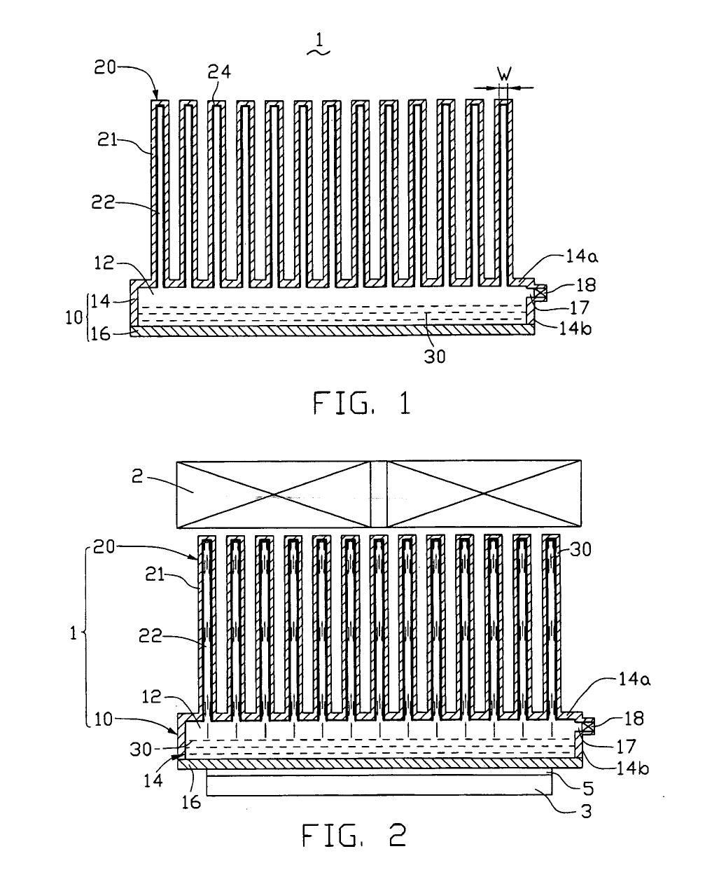

FIG. 1 illustrates a heat sink 1 in accordance with a preferred embodiment. The heat sink 1 includes a base 10, a plurality of fins 20, and a working fluid 30. The base 10 defines a receiving space 12. The fins 20 extend from the base 10. Each fin 20 defines a cavity 22 in communication with the receiving space 12 of the base 10. The working fluid 30 is hermetically contained inside the receiving space 12.

The base 10 includes an upper enclosure 14 and a lower substrate 16. The upper enclosure 14 and the lower substrate 16 cooperatively define the receiving space 12 therein. The upper enclosure 14 and the lower substrate 16 advantageously have an essentially similar thickness and are made from a similar material. The upper enclosure 14 has a top portion 14a and a plurality of side portions 14b. The fins 20 extend from the top portion 14a of the upper enclosure 14. Alternatively, the base 10 could be a hollow integral enclosure.

An opening 17 is advantageously defined on one of the side portions 14b of the upper enclosure 14. The opening 17 is usefully configured for introducing/discharging the working fluid 30 into/off the receiving space 12. Further, the receiving space 12 advantageously has lower pressure than outside environment around the heat sink 1. Thus, the opening 17 is beneficially used to vacuumize the receiving space 12 to attain a predetermined low pressure. The pressure is advantageously in the approximate range from 1.3×10⁻⁴ Pa to 1.3×10⁻¹ Pa. A sealing member 18 is beneficially applied to the opening 17, for sealing the opening 17. The sealing member 18 could be, e.g., a bolt or a screw.

The fins 20 could be in a variety of forms, such as, for example, a micro-fins type, an annular type, or a spiral type. The fins 20 each include sidewalls 21. Each sidewall 21 and the top portion 14a of the upper enclosure 14 are advantageously configured as a whole, for example, by an injection molding method.

Each sidewall 21 of each fin 20 advantageously has a similar thickness to the upper enclosure 14 and the lower substrate 16. This thickness is substantially in the approximate range from 5 millimeters to 10 millimeters. The cavity 22 of each fin 20 has a narrow width W in the approximate range from 1 millimeter to 10 millimeters. A space between adjacent fins 20 is in the approximate range from 1 millimeter to 10 millimeters. The fins 20 and the base 10 are advantageously comprised of a similar material, for example, a thermally conductive material selected from the group consisting of: copper, aluminum, nickel, iron, alumina, aluminum nitride, and combinations thereof.

A wick 24 is advantageously applied to an inner surface of each sidewall 21 of the fins 20, for drawing and introducing the working fluid 30 toward the receiving space 12 via a capillary attraction thereof. The wick 24 could be in a form of, e.g., a wick structure layer or a wick material stuffed in the cavity 22. The wick 24 could be made, beneficially, from a porous material, such as, for example, carbon fibers, carbon nanotubes, sintered copper powder, or micro etched grooves. Further, the wick 24 could, optionally, also be applied to the receiving space 12, i.e., formed on an inner surface of the receiving space 12 or stuffed into the receiving space 12.

The working fluid 30 is beneficially a liquid having properties, such as, high phase change latent heat, good fluidity, steady chemical characteristics, and low boiling point. The working fluid 30 could, advantageously, be comprised of a liquid selected from the group consisting of water, methanol, alcohol, acetone, ammonia, heptane, etc.

The working fluid 30 has preferably a plurality of nano-particles suspended thereinto, for improving thermal conductivity thereof. The nano-particles could, advantageously, be comprised of a thermally conductive material, e.g., carbon nanotubes, carbon nanocapsules, nano-sized copper particles, or any suitable combinations thereof. The nano-particles beneficially occupy about 0.5 to 2 percent by weight in the working fluid 30.

FIG. 2 illustrates an application of the above-described heat sink 1 for dissipating heat from a heat-generating element 3. The lower substrate 16 is thermally coupled to the heat-generating element 3 (e.g., an electronic element), for example, by interposing a thermal interface device (e.g., a thermal interface material) 5 therebetween. A fan 2 is advantageously engaged with the heat sink 1, for promptly cooling down the fins 20. These apparatus above essentially constitute a typical heat management system.

In operation, heat generated from the heat-generating element 3 firstly is transferred to the lower substrate 16 of the heat sink 1 via the thermal interface material 5. Then, the working fluid 30 is vaporized and sequentially attains the cavities 22 of the fins 20. In the cavities 22 of the fins 20, the vapor working fluid 30 goes through a sequential phase change and thereby is condensed into liquid working fluid 30 due to a cooperative cooling action of the fins 20 and the fan 2. The liquid working fluid 30 is drawn back to the receiving space 12 via a capillary attraction of the wick 24 thereby effectuating a heat transfer cycle of the heat sink 1.

Because the combined receiving space 12 and the cavities 22 are vacuumized at a lower pressure, the working fluid 30 is readily vaporized in the receiving space 12 and promptly flows through the cavities 22 of the fins 20. Accordingly, the heat sink 1 inside produces relatively little thermal resistance thereby promoting the thermal efficiency of the heat sink 1. The heat sink 1 can also uniformly cool down the heat-generating element 3 due to a uniform evaporation and fluidity of the working fluid 30 thereby preventing an occurrence of a partial overheating in the heat-generating element 3.

Furthermore, the heat sink 1 includes the vacuumized cavities 22 and receiving space 12, so the entire heat sink 1 is efficiently lightened enough to satisfy a lightweight requirement of current electronic products. Moreover, the opening 17 could provide convenient for introducing or refreshing the working fluid 30, and changing the vacuum degree in the combined receiving space 12 and the cavity 22.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat sink comprising:
a base defining a receiving space;
a plurality of fins extending from the base, each fin defining a cavity in communication with the receiving space of the base; and
a working fluid hermetically contained inside the receiving space.

2. The heat sink of claim 1, wherein the receiving space and the cavity have a lower pressure than outside environment around the heat sink.

3. The heat sink of claim 2, wherein the lower pressure is in the approximate range from 1.3×10⁻⁴ Pa to 1.3×10⁻¹ Pa.

4. The heat sink of claim 1, wherein the base defines an opening configured for introducing/discharging the working fluid into/off the receiving space and vacuumizing the receiving space and the cavity.

5. The heat sink of claim 4, wherein the base comprises an upper enclosure and a lower substrate, the fins extending from the upper enclosure, the opening being defined on a side of the upper enclosure.

6. The heat sink of claim 5, wherein the lower substrate is configured for thermally coupling to a heat-generating element.

7. The heat sink of claim 5, wherein each of the fins has sidewalls, each sidewall and the upper enclosure of the base being configured as a whole.

8. The heat sink of claim 7, wherein the upper enclosure, the lower substrate, and the sidewalls of each fin essentially have a similar thickness.

9. The heat sink of claim 8, wherein the thickness is in the approximate range from 5 millimeters to 10 millimeters.

10. The heat sink of claim 1, wherein the working fluid comprises a liquid and a plurality of thermally conductive nano-particles suspended therein.

11. The heat sink of claim 1, wherein the fins each have an inner surface, a wick being applied to the inner surface.

12. The heat sink of claim 1, wherein the cavity of each fin has a narrow width in the approximate range from 1 millimeter to 10 millimeters.

13. The heat sink of claim 1, wherein a space defined between adjacent fins is in the approximate size range from 1 millimeter to 10 millimeters.

14. A heat management system comprising:
a heat-generating element; and
a heat sink comprising:
a base defining a receiving space therein and coupling with the heat-generating element;
a plurality of fins extending from the base, each fin defining a cavity therein; and
a working fluid hermetically contained inside the receiving space.

15. The heat management system of claim 14, further comprising a thermal interface device interposed between the heat-generating element and the heat sink.

16. The heat management system of claim 14, further comprising a fan engaged with the heat sink.

17. The heat management system of claim 14, wherein pressure inside the receiving space and the cavity is lower than pressure outside around the heat sink.

18. The heat management system of claim 14, wherein the base defines an opening configured for introducing/discharging the working fluid into/off the receiving space and vacuumizing the receiving space and the cavity.
